(19) United States
(12) Patent Application Publication
(10) Pub. No.: US 2014/0278168 A1
(43) Pub. Date: Sep. 18, 2014

(54) ELECTIVE REPLACEMENT INDICATION GENERATION

(71) Applicant: MEDTRONIC, INC., Minneapolis, MN (US)

(72) Inventor: Charles R. Rogers, Maple Grove, MN (US)

(73) Assignee: Medtronic, Inc., Minneapolis, MN (US)

(21) Appl. No.: 13/803,517

(22) Filed: Mar. 14, 2013

(51) Int. Cl. G01R 31/36

(52) U.S. Cl. CPC G01R 31/3679
USPC 702/63

(57) ABSTRACT

This disclosure describes techniques for generating an elective replacement indication (ERI) for an implantable medical device having a non-rechargeable power source. A signal may be sampled that is indicative of a characteristic of the power source. Measurement logic may be configured to obtain samples of a signal indicative of a characteristic of the power source. A control circuit may be configured to determine when a first sample of the signal having a first predetermined relationship to a first threshold is received, and to initiate issuance of an elective replacement indication if a predetermined period of time elapses between receipt of the first sample and receipt of a second sample of the signal having a second predetermined relationship to a second threshold.

### TECHNICAL FIELD

This disclosure is directed to techniques for power management in a device and, more particularly, measurement of battery longevity in the device.

### BACKGROUND

Devices often make use of one or more non-rechargeable power sources, such as batteries, to provide operating power to circuitry of the device. During operation, the charge level of a power source drops due to power consumption by the device. The device may provide some indication of remaining charge as the power source drains.

In the case of implantable medical device that have non-rechargeable power sources, it is desirable to provide a user, such as a patient, with an early warning that the power source is reaching depletion and nearing its End-of-Life (EOL). This early warning, or Elective Replacement Indication (ERI), provides the patient with enough notice so that an elective surgery may be scheduled, if needed, to replace the device prior to the depletion of the power source. If ERI is not provided early enough, the patient may not have enough time to schedule elective replacement surgery before therapy delivery ceases at power source depletion. Therefore, it is desirable that an implantable medical device not provide an ERI indication too close to device EOL.

While it is undesirable to provide an ERI indication too late in the life of the power source, it is also undesirable to provide an ERI indication too early. Providing an ERI too early may result in device replacement before it is really necessary, wasting health care resources and possibly subjecting the patient to unnecessary surgeries over the course of the patient's lifetime.

Therefore, mechanisms are needed to provide accurate ERI indications so that ERI indications are neither provided too early nor too late in the life cycle of the power source.

### SUMMARY

In general, this disclosure describes techniques for issuing an elective replacement indication (ERI) that warns a patient that a non-rechargeable power source of an implantable medical device is reaching end-of-life (EOL). The power source may power electronic circuitry, including therapy and/or sensing circuitry, within the medical device.

In some examples, a processor or other control circuitry may monitor a signal indicative of a characteristic of the power source. In one specific example, the signal is an output voltage level of a battery but the signal could be a different type of signal that is indicative of the state of the power source, such as an impedance or capacitance of the power source.

Monitoring of a signal indicative of a characteristic of the power source may involve comparing values of the signal to one or more threshold values. For instance, a value of the monitored signal may be compared to a first predetermined threshold to determine whether the value of the monitored signal ever attains a first predetermined relationship to this first threshold. As a specific example, this monitoring may determine if an output voltage level of a power source ever attains a relationship of “less than” or “less than or equal to” a first threshold voltage level. If, during the monitoring, the battery output voltage is less than this first threshold value, measurement of a time period may be initiated.

Once measurement of the time period is started because the monitored signal attained a first predetermined relationship to the first threshold, monitoring may continue. Continued monitoring is performed to determine when, if ever, a sampled value of the monitored signal will attain a second predetermined relationship to a second predetermined threshold. This second threshold may, but need not, be the same as the first threshold. Returning to the above example, the second relationship may be “greater than or equal to” or “greater than” such that monitoring is checking for a battery output voltage that rises above a second predetermined voltage level. If the battery voltage attains this second threshold voltage level before the measured period of time exceeds some predetermined length of time (referred to herein as “the ERI threshold time”), processing continues without issuing an ERI indication. On the other hand, if the measured period of time meets or exceeds the ERI threshold time prior to receipt of the sample that has the second predetermined relationship to the second threshold, an ERI indication is issued. In this case, it may be said that a period of time elapsed that was equal in length to at least the ERI threshold time between receipt of the two samples such that the ERI indication should be issued.

In one example, a method is disclosed for monitoring a power source of an implantable medical device. The method comprises sampling a signal indicative of a characteristic of the power source and determining, by a control circuit, when a first sample of the signal having a first predetermined relationship to a first threshold is received. The method may also include issuing, by the control circuit, an elective replacement indication if at least a predetermined amount of time elapses after receipt of the first sample and before receipt of a second sample of the signal having a second predetermined relationship to a second threshold.

For purposes herein, “first sample” refers to a sample that may mark the start of the monitored time period and “second sample” may refer to a sample that will have a second predetermined relationship to the second threshold. If received, such a second sample may mark the end of the monitored time period. It will be understood that these first and second samples are not necessarily literally received first or second, since samples may be received in an on-going manner (either continuously or intermittently) in some examples such that one or more samples are received before the “first” sample, one or more samples may be received between the “first” and “second” samples, and one or more samples may be received after the “second” sample. Thus, discussions concerning “first” and “second” samples are for ease of reference only and should not be considered limiting in regards to any particular order requirements of the samples.

According to examples of the current disclosure, the characteristic may be an output voltage level of the power source. Sampling may comprise sampling a signal indicative of a characteristic of the power source when the power source is lightly loaded. Sampling of the signal may be performed at least some predetermined amount of time after an occurrence of a most-recent high-current event. Sampling may also comprise obtaining a value indicative of the signal at substantially a time the value is obtained.

In some cases, at least one of the first and second predetermined relationships may be defined based, in part, on a period of time. In examples, the first and second thresholds may be substantially equal. According to yet other aspects, a user may be allowed to select at least one of the first threshold, the second threshold, the first relationship, the second relationship and the predetermined amount of time. At least one of the first threshold, second threshold, and the predetermined amount of time may be automatically adjusted in some cases.

The method may also comprise monitoring (or measuring a length of) a time period that follows receipt of the first sample, and discontinuing monitoring of the time period if the second sample is received prior to expiration of the predetermined amount of time. Monitoring the time period may comprise starting a timer and discontinuing monitoring may comprise clearing the timer.

In another example, a system is disclosed. The system comprises a power source configured to be implantable within a patient, measurement logic configured to obtain samples of a signal indicative of a characteristic of the power source, and a control circuit configured to determine when a first sample of the signal having a first predetermined relationship to a first threshold is received, and to initiate issuance of an elective replacement indication if at least a predetermined amount of time elapses following receipt of the first sample and before receipt of a second sample of the signal having a second predetermined relationship to a second threshold. The measurement logic may be configured to obtain samples of an output voltage level of the power source and/or to obtain samples during a time when the power source is lightly loaded. Alternatively or additionally, the measurement logic may be configured to obtain samples that are each indicative of a value of the signal at the time the sample is obtained. In some cases, the first predetermined relationship is “less than”, or “less than or equal to”, and the second predetermined relationship is “greater than or equal to” or “greater than”, respectively. The first and second thresholds may be substantially equal to one another. The system may comprise a user interface to allow a user to programmably select at least one of the first threshold, the second threshold and the predetermined amount of time.

The control circuit, in some cases, may be configured to automatically adjust at least one of the first threshold, the second threshold, and the predetermined amount of time. An implantable medical device may comprise the control circuit, an external device (e.g., a programmer) may comprise the control circuit, or both the implantable medical device and the external device may comprise the control circuit. The control circuit may be configured to start the timer upon receipt of the first sample and to clear the timer upon receipt of the second sample if the second sample is received prior to expiration of the predetermined period of time. The timer may be configured to measure the predetermined amount of time, and the control circuit may be configured to initiate issuance of the elective replacement indication if the timer expires before receipt of the second sample of the signal having the second predetermined relationship to the second threshold.

Another aspect relates to an implantable medical device comprising a power source, measurement logic configured to obtain samples of a signal indicative of a characteristic of the power source, and a control circuit configured to determine when a first sample of the signal having a first predetermined relationship to a first threshold is received, and to initiate issuance of an elective replacement indication if at least a predetermined period of time elapses following receipt of the first sample and before receipt of a second sample of the signal having a second predetermined relationship to a second threshold. The power source may be a medium-rate battery. The device may comprise a timer configured to time the predetermined amount of time. The timer may further be configured to determine when to obtain the samples. The control circuit may be configured to cause the measurement logic to obtain the samples only during time periods wherein the power source is lightly loaded.

Another aspect of the disclosure relates to a non-transitory storage medium storing instructions to cause a control circuit to receive samples of a signal indicative of a characteristic of the power source, to determine when a first sample of the received samples has a first predetermined relationship to a first threshold and to issue an elective replacement indication if a predetermined period of time elapses after receipt of the first sample and before receipt of a second sample of the signal having a second predetermined relationship to a second threshold.

The details of one or more aspects of the disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 is a schematic diagram illustrating an implantable medical device (IMD) system including an IMD and an external programmer.

FIG. 2 is a block diagram illustrating an example device that may be configured to estimate a charge level of a power source in a device.

FIG. 3 is a graph illustrating an example of using averaged values to provide an ERI indication.

FIG. 4 is a graph illustrating how use of signal aggregation can result in the false issuance of ERI.

FIG. 5 is a graph illustrating use of non-aggregated signal values for issuing ERI.

FIG. 6 is another timing diagram illustrating techniques according to the current disclosure.

FIG. 7 is another timing diagram illustrating techniques according to the current disclosure.

FIG. 8 is a flow diagram illustrating one embodiment of a method according to the current disclosure.

FIG. 9 is a flow diagram illustrating an example method for adapting parameters according to the current disclosure.

FIG. 10 is a flow diagram illustrating a method of acquiring samples according to the current disclosure.

### DETAILED DESCRIPTION

Various aspects of this disclosure relate to providing an elective replacement indication (ERI) for an implantable medical device. Implantable medical devices often include one or more non-rechargeable power sources such as prime-cell batteries. During operation, the charge level of these types of power sources drops due to power consumption by the device. In advance of the power source reaching the end of its useful life, it may be desirable to provide the user with an ERI indication that informs the user that the power source is approaching end-of-life (EOL). This ERI indication will give the user time to plan to address this situation, as by having the medical device replaced, which will generally involve scheduling an elective surgery. If this ERI warning is not provided well enough in advance of the device end-of-life, the user may not have enough time to schedule device replacement prior to the time the device ceases to provide therapy because of power source depletion. This may leave the patient without therapy for some period of time.

In view of the foregoing, it is desirable to provide a mechanism for accurately indicating ERI well-enough in advance to allow a user to adequately plan for device replacement, including elective surgery. Generally, it is desirable to provide an ERI indication at least 90 days prior to providing the EOL indication informing the user that the power source has reached its end-of-life.

While it is important to provide the ERI indication early enough to allow the user to plan for a replacement surgery, if appropriate, it is also important not to provide the ERI indication too early. If the ERI indication is provided too soon, the device may be explanted a substantial amount of time before replacement is actually necessary. Replacing a device before it is really necessary may subject the patient to needless surgeries over the course of the patient's lifetime and may also waste health care resources.

Determining when to issue an ERI notification may involve monitoring characteristics of the power source of the IMD. These characteristics indicate when the power source is nearing an end to its useful life. For example, in the case of various types of batteries, including Li—CFx batteries having lithium anodes and CFx cathodes, it is known that the battery output voltage remains relatively flat during early stages of depletion, but drops off rather sharply before EOL. This is due, in part, to the internal resistance of these batteries, which is relatively linear as a function of energy depletion until near EOL, at which time the resistance curve exhibits a “knee” where internal resistance begins to rise rapidly. Monitoring for the change in impedance or voltage exhibited at this “knee” in the curve can provide a useful indication as to how long the battery has prior to end-of-life.

As may be appreciated, characteristics such as voltage, capacitance, and impedance of various types of power sources may be monitored to detect changes over time such as those discussed above. These characteristics may be used by circuitry of the IMD itself and/or communicated to an external device (e.g., via telemetry) so the IMD and/or an external device may determine when the ERI notification should be issued in advance of power source depletion.

Historically, tracking changes in power source characteristics over time has involved use of aggregation mechanisms. As a specific example, the output voltage of a battery may be periodically sampled. Sampling may occur, for instance, once every minute, half-hour, hour, day or at some other predetermined sampling time. Aggregation may then be used to determine a voltage level from multiple samples, such as by calculating an average value of the N most recent samples. In some cases, N represents all of the samples collected over some predetermined period of time (e.g., the past 12 hours, the past day, the past two days, the past four days, and so on.) Any such predetermined period of time could be used. In other cases, N may be selected based on the number of samples considered necessary to obtain a representative average without regard to the period of time over which the samples are collected.

Once an aggregate value is determined using mechanisms such as those discussed above, this aggregate value (e.g., a “rolling” average) may then be compared to some predetermined replacement value. For instance, if an aggregate voltage level based on a rolling average of multiple voltage values drops below the predetermined replacement voltage value, it may be determined that the battery is nearing EOL such that the ERI indication should be issued.

Using values developed by aggregation mechanisms (e.g., average values, median values, etc.) rather than the monitored values themselves has been considered useful in preventing transient fluctuations in the monitored signal from falsely triggering ERI. Such fluctuates may be caused, for instance, by operations that temporarily draw a relatively high amount of current from the power source such that the power source exhibits changes in a monitored characteristic for a relatively short period of time. For example, a telemetry session initiated to allow the IMD to exchange information with an external device may draw a large amount of current from the power source. This is particularly true for long-range telemetry that transfers data via E-field transmission rather than via H-field (inductive) transmission. As another example, a sensor such as an accelerometer that may be used to determine patient posture and/or activity may draw a relatively large amount of current during use. This high-current event may cause the output voltage of the power source to temporarily dip to a low level for some relatively short period of time. Such a high-current event is of a type that will draw a current that is beyond the normal operating current supplied by the battery, and may be referred to as a pulsed current.

After the high-current event ceases (e.g., the telemetry session is ended) the battery output voltage will eventually recover (assuming the power source is not nearing EOL) such that output voltage levels may approximate those that existed prior to the high-current event. A momentary drop in the output voltage during the high-current event should not trigger an ERI indication since the excursion in battery voltage is only the result of the temporary high current draw and is not truly indicative of EOL. In such cases, use of aggregation techniques (e.g., to determine average, median, or some other aggregate values) performs a low-pass filtering function to effectively filter out these temporary excursions, ensuring that ERI is not falsely triggered well before the device is ready for replacement.

Use of aggregated values of a monitored power source characteristic may be usefully employed when using high-rate chemistry power sources. Such power sources may be characterized, in some examples, by a typical discharge current of less than 100 μA and a pulsed current of greater than 1000 mA. In the case of high-rate chemistry power sources, fluctuations of the type described above caused by high-current events are not very long. As a result, aggregated values (e.g., averaged voltage levels) will not have time to reach a threshold level that would trigger an ERI indication before recovery of the power source occurs. In such cases, false triggering of ERI will generally not occur.

Some battery technologies are “medium rate chemistry” batteries that have slower recovery times following a large current-draw event. For instance, Li—CFx batteries have lithium anodes and CFx cathodes. Such batteries are sometimes referred to as “pure CFx” batteries. Another example of a medium rate chemistry battery may be referred to as a hybrid Li—CFx/SVO chemistry that utilizes lithium anodes and a combination of CFx and Silver Vanadium Oxide (SVO) for the cathodes. Other examples include manganese dioxide (Li—MnO₂) and thionyl chloride (Li—SOCl₂) batteries. These batteries may be characterized by a basic load current of less than 100 μA and a pulsed current of between 1 and 100 mA.

Medium rate batteries are characterized by an output voltage that may drop markedly during high-current events and then subsequently recover relatively slowly following cessation of the event. This is particularly true when such batteries are subjected to high-current events that continue for an extended period of time. For instance, a long-range telemetry session between an IMD and an external device may subject the battery to a large current draw that may continue for fifteen minutes or even longer. Following such an event, recovery periods for medium-rate batteries may be on the order of three or more days, depending on the charge level of the battery. While the battery voltage may drop substantially during such an event, and may remain at depressed levels for an extended period of time after the event, the battery voltage may eventually recover to levels that approximate the levels prior to the high-current event. Although such a high-current event may deplete battery charge such that the battery voltage may never again rise precisely to the pre-event levels, the battery is never-the-less usable, and may remain usable for a substantial period of time after the high-current event. Therefore, it is undesirable to allow this type of high-current event to falsely trigger an ERI indication.

As may be appreciated from the foregoing, use of aggregated values to determine ERI may result in the false triggering of ERIs for some power sources, such as medium-rate chemistry batteries. This is because the extended time periods during which the monitored power source characteristic (e.g., output battery voltage) deviates from the pre-event levels (e.g., drops below a voltage threshold) will pull an aggregated value such as a rolling average below an ERI threshold. This will falsely trigger an ERI indication even though the battery is not approaching end-of-life.

In accordance with the current disclosure, instantaneous values of a monitored characteristic (output voltage, battery impedance, battery capacitance, etc.) may be used to trigger ERI rather than using an aggregated value (e.g., average or median value, etc.) obtained from two or more such instantaneous values. As used herein an instantaneous value refers to a value that reflects the state of the power source substantially at the time the value was obtained. This instantaneous value may also be referred to herein as an individual sample, which is indicative of a state of the power source at a time the sample was acquired. An instantaneous value or sample is in contrast to an aggregated value that is obtained from multiple instantaneous values (e.g., the rolling average discussed above) and which is not necessarily representative of the state of the power source at the time any one of the multiple values was acquired.

According to one example of the current disclosure, a signal that is indicative of a characteristic of a power source may be sampled. As discussed above, this may involve obtaining values, or samples, of a voltage signal indicative of an output voltage of the power source. As another example, this may involve sampling a signal indicative of an internal impedance or capacitance of the power. The sampled values are instantaneous values, meaning each sample indicates a value of the voltage signal at substantially a time the sample is acquired.

Each sampled value may be compared to a first threshold. If even one individual sample has a value having a first predetermined relationship to the first threshold, measuring (or “monitoring”) of a length of time period may be initiated. A timer may be started, for instance, to measure the time period following receipt of the first sample. As one specific example, if even one sampled value of an output voltage signal of the power source is less than this first threshold, measuring of the length of the time period following receipt of this sample may be initiated.

Next, monitoring of the power source characteristic may continue by obtaining, or sampling, additional instantaneous values of the signal being monitored. Each such sampled value may be compared to a second threshold, wherein this second threshold may, but need not, be the same as the first threshold. If such a sample is obtained before the time period following receipt of the first sample reaches some predetermined amount of time (such predetermined amount of time being referred to herein as the “ERI threshold time”), no ERI indication is generated. For instance, the timer may simply be cleared in this case, and no action will be taken. On the other hand, if such a sample is not obtained prior to expiration of the ERI threshold time, an ERI indication is generated. According to some examples, the ERI threshold time may be an amount of time ranging from one to five days. In a particular embodiment, the ERI threshold time is three days.

An ERI indication may be issued in several situations. For example, an ERI indication may be issued because a sample of the signal having a second predetermined relationship to the second threshold is never received. This may occur, for instance, because the power source is too depleted to ever recover back to a state wherein the second threshold may be attained. Therefore, the monitored time period following receipt of the first sample will exceed the ERI threshold time while waiting for a sample that has the second predetermined relationship to the second threshold. This will trigger issuance of the ERI indication. As another example, although a second sample of the signal may be received that has the second predetermined relationship to the second threshold, this sample may be received after the monitored time period reaches the ERI threshold time. This may occur because, although the power source is still able to recover in some capacity, it is sufficiently depleted to be unable to recover in a manner that is timely enough to meet the ERI requirements of the system. Again, as a result, the time between the first and second samples will exceed the ERI threshold time, and an ERI indication will be issued.

In some embodiments, when a first sample having a first relationship to the first threshold is obtained, a timer may be loaded with the ERI threshold time. The timer may then count down while monitoring continues to look for a sample having the second relationship to the second threshold. If the timer expires (i.e., the ERI threshold time elapses) without having received this second sample, an ERI indication is generated. Otherwise, the timer may simply be cleared and sampling may return to checking for sampled values having the first predetermined relationship to the first threshold in the manner previously described.

The foregoing may be further illustrated by a more specific example. Assume again that in this case the power source is a medium rate battery and the monitored characteristic is battery output voltage. In this simple example, the first and second thresholds are selected to be the same threshold voltage level V1. Samples are acquired of the battery output voltage. Each sample is compared to V1. Once a first sample is obtained that is less than V1, measuring of a time period may be started at a time T1, which marks substantially the time of receipt of this first sample. Thereafter, additional samples may be obtained. Each additional sample may be compared to the second threshold voltage level (also V1 in this case) to determine if a second sample is obtained that is greater than, or equal to, V1. If such a sample is acquired before the monitored time period equals, or exceeds, the ERI threshold time, the monitored time is reset (as by resetting a timer) and no ERI indication is generated. However, if the second sample is either never received, or is received after the measuring time period reaches the ERI threshold time, it may be determined that the power source is either not going to recover to adequate levels, or is recovering so slowly that it may be legitimately concluded EOL is approaching. Therefore, an ERI indication is generated.

In the foregoing manner, individual sample values are obtained. Each such sample, which is an indication of a state of the power source at substantially a time the sample was obtained, may be compared to a threshold value. The results of the comparison may determine whether an ERI indication is to be generated. This is in contrast to prior art approaches that utilize some composite, or aggregate, value derived from multiple values (e.g., an average or median value obtained from multiple voltage samples) to determine when to generate an ERI indication.

Various parameters used in the mechanisms described herein to determine when to trigger issuance of an ERI indication may be programmably selected by a manufacturer, an end-user (e.g., a clinician or patient) or some other party. For instance, one or more of the first and second thresholds, the first and second predetermined relationships to these first and second thresholds, and the ERI threshold time may be programmable. In some cases, even the characteristic that is being monitored (e.g., voltage, impedance, capacitance, etc.) may be selected. This allows the ERI methods to be adapted to the specific power source chemistry, to the type of therapy being delivered, to user preferences and requirements, and so on.

In some other examples, various parameters described herein as being used to determine when to trigger issuance of an ERI indication may be selected based on a monitored characteristic of the power source or some other aspect of the system. For instance, one or more of the parameters described above, including the first and second thresholds, may be programmably re-selected periodically based on depth of discharge or a level of charge of the power source. This allows the ERI algorithm to be adapted over the life of the power source. The depth of discharge or level of charge of the power source could be indicated, for instance, by a Coulomb counter, which may be used to monitor charge drawn from the power source over the life of the system. Early in the useful life of the power source, first values may be selected for one or more of the programmable aspects described above. Later in the useful life of the power source, as determined by a Coulomb counter indication, different values may be selected for a same, or different set, of the programmable aspects set forth above. In this manner, the mechanism used to generate an ERI indication may be adapted based on one or more characteristics of the power source, such as depth of discharge.

Although examples discussed herein describe use of individual, non-aggregated battery voltage measurements to trigger ERI, this is for illustration purposes. Other non-aggregated values indicative of a current state of the power source (e.g., battery) may be used instead of voltage to determine when to issue an ERI. For instance, in some cases, individual instantaneous impedance measurements may be periodically taken. A high-current event may cause a temporary change in the impedance (e.g., a temporary increase in impedance). A first sample value indicative of the impedance of the battery may indicate the impedance value is above a first impedance threshold value, and may therefore mark the start of a monitored time period. Individual samples may continue to be collected until the monitored time period has a length that is equal to or greater than (or in some embodiments merely “greater than”) the ERI threshold time without receiving a second sample value indicative of impedance of the battery that is at, or below a second impedance threshold.

Still other types of parameters that are indicative of a current state of the power source may be monitored in accordance with techniques described herein. For example, a battery capacitance may be monitored for this purpose. The first and second thresholds, types of first and second relationships used with these thresholds, the ERI threshold time, and other selectable parameters may be selected based in part, on the particular chemistry of the power source, a type of characteristic being monitored (e.g., battery impedance, battery capacitance, battery voltage, etc.), needs of the particular user, and so on.

Thus, the current disclosure provides example systems and methods for monitoring a power source of an implantable medical device so that an ERI indication may be provided that is based on individual discrete signal samples. In some examples, these samples are each indicative of a value of a monitored power source characteristic at substantially a time the sample was acquired. These values are each based on one respective measurement and are therefore said to be “non-aggregate” values, versus aggregate values that are each based on multiple measurements.

This mechanism may comprise sampling a signal indicative of a characteristic of the power source. Sampling may be accomplished, for instance, by a sampling circuit that periodically acquires a signal value indicative of the monitored signal at substantially that moment in time. Generally such samples will be collected a regular intervals. As one example, a sample of an output voltage of a battery may be obtained once every minute, every hour, every twelve hours, every day, and so on. Such a sample may indicate the output battery voltage at substantially the time the sample was obtained, as may be measured by the sampling circuit or some other circuit. It may indicate an instantaneous value of the voltage, rather than a value that is representative of the battery voltage over a time period during which multiple samples was acquired. Sampling may be used to acquire a sequence of individual sample values that are used in the manner described above.

In some examples, a sampling time (a time represented by one sample) may approach zero such that acquisition of values of a signal is substantially continuous, and the number of values collected approaches infinity. In this case, samples may be selected from this continuous collection of data (e.g., every Nth sample) to be compared to the first or the second thresholds according to the current disclosure. Thus, there is no limitation on any amount of time that need separate contiguous samples, and the sampling methods need not be considered intermittent, but instead could be considered a continuous recording of a signal waveform. Sampling rates need only be limited by an amount of processing time, power, storage, and other resources devoted to this task.

While is some cases, samples may be selected based on a predetermined sampling time, or a predetermined sample interval (e.g., every Nth sample), in other cases, it may be desirable to exclude some samples from use when employing techniques described herein. For instance, it may be undesirable to use samples collected during times when the power source is heavily loaded, such as during a high-current event. During these time periods, the monitored characteristic of the power source may be more dependent on the amount of charge being drawn from the power source at that moment in time than based on the state of the power source. Therefore, monitoring the characteristic of the power source during these time periods may not provide very much information concerning the long-term state of the power source, and in fact, may unnecessarily waste processing resources and consume power.

In accordance with the foregoing, the system may monitor for heavy load conditions. A heavy load condition for a system that includes a medium rate power source may be, for instance, a condition that draws more than some predetermined percentage or predetermined amount of current beyond the “normal operating current”. An example of normal operating current for a medium-rate battery may be 20 μA. A heavy load condition may comprise a current of between 0.5 mA and 20 mA, for instance. This type of current may be drawn from power source during a high-current event.

It may be desirable to stop collecting samples during periods of heavy loading since such collection and processing of the samples will only waste processing and other resources while providing only incremental value. These samples do not provide a good indication of the recovery ability of the battery (and hence an indication as to whether EOL should be issued.) Instead, once the heavy loading condition is known to have ceased and the power source is again operating under a normal loading condition, sampling may resume.

In some cases, a control circuit or other processing circuit of the IMD may periodically enter an idle state. During this idle period, the power source is lightly loaded and only a normal operating current is being drawn from the battery. This operating current may be under 1 mA, for instance. In some examples, the normal operating current is between 10 and 50 μA when lightly loaded. The processor may periodically exit this idle state (e.g., by receiving an interrupt) at a regular or semi-regular basis to perform certain tasks, which may be higher-current tasks. These tasks could include delivering a drug bolus, transferring data via a telemetry session, or performing some other periodically-required operation. Sometime after exiting the idle state and before any of these higher-load operations are initiated, it may be desirable for the processor to obtain a sample of a monitored power source characteristic according to techniques described herein. For instance, this may be one of the first tasks performed by the processor when the processor exits the idle state (i.e., “wakes up”). At this time, it may be known that the system is operating under a normal operating scenario wherein the system is lightly loaded and it is therefore advantageous to collect the sample at this time. Moreover, it may be assumed that the power source has been recovering throughout the idle state and that no high-current events were occurring during this idle time. As a result, a sample collected at the end of the idle state may be more informative as to the state of the power source, and in particular, the manner in which the power source is recovering from any previous high-current event.

FIG. 1 is a schematic diagram illustrating a system 106 that includes an implantable medical device (IMD) 110 and an external programmer 116 shown in conjunction with patient 108. In accordance with the current disclosure, IMD 110 may comprise a non-rechargeable power source that will discharge such that the IMD 110 must be replaced at the end of the useful life of the power source. As such, an ERI indication should be provided by IMD 110 sometime prior to (e.g., 90 days) the EOL of the power source to give the patient time to schedule a replacement procedure.

As shown in FIG. 1, leads 112A, 112B are implanted adjacent a spinal cord 114 of patient 108, e.g., for spinal cord stimulation (SCS) to alleviate pain. However, the techniques described in this disclosure are applicable to leads implanted to target any of a variety of target locations within patient 108, such as leads carrying electrodes located proximate to spinal cord 114, pelvic nerves, peripheral nerves, the tibial nerve, the stomach or other gastrointestinal organs, or within the brain of a patient. In other cases, the lead may be within or proximate to the heart to provide pacing, synchronization, defibrillation, or other types of cardiac therapies. Also, techniques of this disclosure are applicable to other IMDs, such as those that deliver substances, e.g., drugs, to a patient. In some examples, the IMD may provide sensing capabilities (e.g., sensing various signals) in addition to, or instead of, providing therapy to patient 108.

In the example of FIG. 1, stimulation energy is delivered from IMD 110 to spinal cord 114 of patient 108 via one or more electrodes carried by axial leads 112A and 112B (collectively “leads 112”) implanted within the patient. In various applications, such as spinal cord stimulation (SCS), the adjacent implantable leads 112 may have longitudinal axes that are substantially parallel to one another. Various combinations of electrodes carried by the leads 112 and/or on the housing of the IMD 110 may be used to deliver electrical stimulation, including combinations of electrodes on a single lead or combinations of electrodes on both leads. In the case of lead electrodes, the electrodes may be ring electrodes that extend around a circumference of a lead body, or segmented electrodes that extend only part-way around the circumference of the lead body. Also, in some examples, electrodes may be carried by paddle leads in which an array of electrodes may be arranged in a two-dimensional pattern, e.g., as columns or rows of electrodes, on a common planar lead surface.

In the example of FIG. 1, leads 112 carry electrodes that are placed adjacent to the target tissue of spinal cord 114. In particular, leads 112 may be implanted in the epidural space adjacent spinal cord 114, and coupled to an implanted IMD 110. In the example of FIG. 1, stimulation energy may be delivered to spinal cord 114 to eliminate or reduce pain perceived by patient 108. However, IMD 110 may be used with a variety of different therapies, such as peripheral nerve stimulation (PNS), peripheral nerve field stimulation (PNFS), deep brain stimulation (DBS), cortical stimulation (CS), pelvic floor stimulation, gastric stimulation, stimulation of the heart or other organ or tissue and the like. The stimulation may be configured to alleviate a variety of symptoms or conditions such as chronic pain, tremor, Parkinson's disease, epilepsy, urinary or fecal incontinence, sexual dysfunction, obesity, or gastroparesis. The stimulation delivered by IMD 110 may take the form of stimulation pulses or continuous waveforms, and may be characterized by controlled voltage levels or controlled current levels, as well as pulse width and pulse rate in the case of stimulation pulses.

A user, such as a clinician, physician or patient 108, may interact with a user interface of external programmer 116 to program stimulator 110. Programming of external programmer 116 may refer generally to the generation and transfer of commands, programs, or other information to control the operation of IMD 110. For example, programmer 116 may have control logic to transmit programs, parameter adjustments, program selections, group selections, or other information to control the operation of IMD 110, e.g., by wireless telemetry. Parameter adjustments may refer to initial parameter settings or adjustments to such settings. A program may specify a set of parameters that define stimulation. A group may specify a set of programs that define different types of stimulation, which may be delivered simultaneously using pulses with independent amplitudes or on a time-interleaved basis.

Control logic of programmer 116 may be provided to perform one or more steps according to techniques described herein, such as processing signal samples acquired by logic of IMD 110 and transferred to the programmer for use in determining whether to issue an ERI indication.

In some cases, a user may interact with user interface of external programmer 116 to select and program one or more parameters used by an ERI technique according to the current disclosure. Such parameters may include one or more of first and second thresholds, first and second relationships to these thresholds, an ERI threshold time, and even the characteristic of the power source that is being monitored in some cases.

According to the current disclosure, programmer 116 may receive commands, data, or other information from IMD 110. For instance, programmer 116 may receive an ERI indication from IMD 110 indicating that a limited time remains (e.g., 90 days) until EOL of the power source of the IMD 110 is reached. In response to receipt of this ERI, programmer may generate an audible tone, provide a vibration, cause some message or other visible information (e.g., an icon) to be displayed on a display screen, or otherwise notify the user of the ERI. In response, the patient may schedule an elective replacement procedure to have IMD 110 replaced, or may take other appropriate action to avoid reaching EOL.

In some cases, external programmer 116 may be a physician or clinician programmer if it is primarily intended for use by a physician or clinician. In other cases, external programmer 116 may be a patient programmer if it is primarily intended for use by a patient. In general, a physician or clinician programmer may support selection and generation of programs or parameters by a clinician for use by IMD 110, whereas a patient programmer may support more limited adjustment and selection of such programs or parameters by a patient during ordinary use.

IMD 110 may be implanted in patient 108 at a location minimally noticeable to the patient. For spinal cord stimulation (SCS), as an example, IMD 110 may be located in the lower abdomen, lower back, or other location to secure the stimulator. Leads 112 may be tunneled from IMD 110 through tissue to reach the target tissue adjacent to spinal cord 114 for stimulation delivery. At distal portions of leads 112 are one or more electrodes (not shown) that transfer stimulation energy from the lead to the tissue. The electrodes may be electrode pads on a paddle lead, circular (i.e., ring) electrodes, surrounding the body of leads 112, segmented electrodes arranged at different axial and rotational positions around a lead, conformable electrodes, cuff electrodes, or any other type of electrodes capable of forming unipolar, bipolar or multipolar electrode configurations.

FIG. 2 is a block diagram illustrating an example IMD 110 that may be configured to determine an ERI indication according to the current disclosure. IMD 110 may include power source 204, measurement logic 208, control circuit 210, storage device 212, analog-to-digital (A/D) converter 214, telemetry module 216, timer 218 and ERI indicator 220. Although shown as separate units in FIG. 2, in some examples, Coulomb counter 206, measurement logic 208, A/D converter 214, ERI indicator 220 and timer 218 may be incorporated as a part of control circuit 210. IMD 110 may include additional components not shown for purposes of clarity. Various other components may be provided within IMD 110 based on the functionality of IMD 110. Aspects of this disclosure should not be considered limited to the example components described above.

In some examples, IMD 110 may include sensing module 213 to sense physiological signals or other parameters associated with a patient, and/or therapy module 211 to deliver therapy to a patient. Sensing module 213 may include any type of one or more sensors such as blood glucose sensors, pressure sensors, heart rate sensors, posture and/or activity sensors (e.g., accelerometers) and/or virtually any other type of sensor for obtaining physiological data indicative of the patient condition or a condition of the system as a whole. In some cases, one or more of the sensors of sensing module 213 may draw a relatively large amount of current such that obtaining measurements with the sensor may be considered a high-current event.

Therapy module 211 and sensing module 213 are shown for illustration purposes and may not be required in every example of IMD 110. Furthermore, in some examples, IMD 110 may include therapy module 211, but may not include sensing module 213. In some examples, IMD 110 may include sensing module 213, but may not include therapy module 211.

If IMD 110 includes therapy module 211, therapy module 211 may be coupled to one or more electrodes. In some cases, some of the electrodes may be carried on one or more leads. Therapy module 211 may be configured to provide electrical stimulation therapy to a patient to address at least one physiological condition experienced by the patient. In some examples, therapy module 211 may be a drug delivery module configured to provide medication to a patient in accordance with a drug delivery schedule.

In some examples that include sensing and therapy modules, sensing module 213 may be coupled to the same electrodes as therapy module 211 to sense physiological signals or other parameters associated with the patient. In some examples, sensing module 213 may be coupled to electrodes designated for sensing purposes that are different than the electrodes coupled to therapy module 211. Instead of or in addition to being coupled to electrodes, sensing module 213 may be coupled to different types of sensors to sense physiological signals or parameters associated with the patient. For example, sensing module 213 may be coupled to pressure sensors, blood flow sensors, respiration sensors, and the like. It should be noted that aspects of this disclosure are not limited to the example functions of therapy module 211 and sensing module 213 described above, and other types of therapy and sensing operations may be practiced according to the current disclosure.

Power source 204 may be any unit that provides power to the components of IMD 110 by discharging charge that is stored on power source 204. Power source 204 may be a single battery or multiple batteries that are tied together in parallel or in series to form a single power source. Also, power source 204 may be one or more capacitors or super capacitors tied together in parallel or in series to form a single power source. In examples where IMD 110 includes multiple different power sources, aspects of this disclosure may be extendable to each power source.

For purposes of illustration, aspects of this disclosure are described in the context of power source 204 being one or more batteries. In a particular embodiment, power source 204 may be a non-rechargeable medium rate battery Examples of such batteries include, but are not limited to, those comprising pure CFx chemistries such as Li—CFx chemistries, hybrid Li—CFx/SVO chemistries, CFx/SVO chemistries and other medium rate batteries. Other examples include manganese dioxide (Li—MnO₂) and thionyl chloride (Li—SOCl₂) batteries. Power source 204 may provide power to one, some, or all of the various components of IMD 110. Power source 204 discharges due to the power consumed by the various components of IMD 110. Due to the discharging, power source 204 may need to be replaced periodically to ensure that power source 204 does not become fully depleted such that battery EOL is reached. Aspects of this disclosure provide techniques to determine when to issue an ERI indication in advance of the EOL. An ERI is preferably issued at least 90 days prior to the end-of-life of power source 204 to allow a user to plan an elective surgery.

Referring back to FIG. 2, storage device 212 or a cache of control circuit 210 may store various values associated with the techniques described herein. Such values may include the values of samples acquired for the monitored power source characteristics. In some cases, storage device 212 may further store one or more of the first and second threshold values to which the samples are compared, the first and second relationships used to compare samples to the first and second thresholds, respectively (e.g., “greater than”, “less than”, etc.), the ERI threshold time, and any other value that may be required by techniques described herein to determine whether an ERI indication should be generated.

In some cases, storage device 212 may store information about power source 204, such a manufacturer specifications that may indicate what type of chemistry is used by the power source. Such information may be used to programmably select aspects such as the first and second thresholds, first and second relationships, the ERI threshold time, and so on.

Timer 218 may provide the time to control circuit 210. Timer may comprise a timer implemented in hardware, software and/or firmware. In some examples, timer 218 may provide a clock from which control circuit 210 synchronizes its operation. In some examples, timer 218 may be initialized to zero and may start incrementing to indicate the amount of elapsed time. Timer 218 may also be used to determine a time at which samples are to be acquired, and in some cases, to provide a timestamp to be associated with samples of the monitored power source signal values. Timer may also be used to measure a time period between the first and second samples to determine whether it exceeds the ERI threshold time.

According to some embodiments, when a first sample is detected by control circuit 210 that has a first predetermined relationship to a first threshold, control circuit 210 may cause timer 218 to start timing an ERI threshold time. This may be accomplished, for instance, by initializing timer 218 to the ERI threshold time and starting the timer so that it begins counting down towards zero. If control circuit 210 acquires a second sample that has a second predetermined relationship to a second threshold before this ERI threshold time elapses (e.g., via timer expiration), control circuit may cause the timer 218 to stop timing this ERI threshold time (e.g., by clearing the timer). On the other hand, if control circuit 210 does not acquire a second sample that has the second predetermined relationship to the second threshold before this ERI threshold time elapses and the timer expires, timer 218 may provide an indication (e.g., an interrupt) to control circuit. The control circuit 210 may then cause an ERI indication to be issued.

As discussed above, timer 218 may further be used to determine when samples are to be obtained. For instance, samples may be obtained at predetermined time periods, such as one sample each minute, one each hour, and so on. The timer 218 may be used to track these time increments and to control when a new sample is acquired. For instance, timer 218 may provide a signal (such as an interrupt) to control circuit 210 to indicate when a next measurement indicative of a characteristic of power source 204 should be acquired. This may cause control circuit to poll measurement logic 208 to provide a signal sample to A/D converter 214, which may provide the sample to control circuit 210. Alternatively, timer 218 may send a signal (e.g., an interrupt) directly to measurement logic 208 to cause measurement logic 208 to take another sample.

In one example, control circuit 210 is a processor that periodically enters an idle state. The idle state may be entered at time increments indicated by timer 218. In some cases, timer 218 may generate an interrupt to control circuit 210 to cause control circuit 210 to exit this idle state and perform certain tasks. One of the first tasks performed upon exiting the idle state may be to obtain a sample of a monitored characteristic of power source 204. The sample may be taken before any other tasks are performed that would place a high load on the power source 204. In this manner, control circuit 210 may take a sample during a lightly-loaded period when power source 204 has had a maximum amount of time to recover from any previous tasks that placed a heavy load on power source 204 prior to control circuit 210 entering the most-recent idle state. For instance, power source 204 may have had the entire idle period to recover from any previous high-current event. A sample taken at this time may provide more information on the state of the power source than if the power source is either heavily loaded during the acquisition of a sample, or was recently heavily loaded.

In some cases, timer 218 may generate timestamps to be assigned to one or more of the samples. For instance, a first timestamp may be generated by timer 218 when a first sample is received having a first predetermined relationship to a first threshold. A second timestamp may be generated by timer 218 when a second sample is received having a second predetermined relationship to a second threshold. The time between the first and second samples may be determined as the difference between timestamps. The times between first and second samples may be used for information purposes. For example, even though first and second samples may have been received close enough in time so that an ERI indication was not issued, it may never-the-less be desirable to know how close in time these samples were received. For instance, if the samples were received far enough apart that the ERI threshold time almost elapsed prior to receipt of the second signal, it may be desirable to generate an alert. It may be that high current events (telemetry sessions) are occurring for longer than anticipated when the ERI threshold time was selected (e.g., programmably selected.) Therefore, it may be desirable to determine that because of this, the system is coming close to issuing an ERI indication even though the battery is not actually near EOL. In this case, it may be desirable to re-program the ERI threshold time so that the ERI indication is not triggered too early. Thus, the timer may be used to gain useful information regarding the performance of the system.

In some examples, IMD 110 may further comprise Coulomb counter 206. Coulomb counter monitors charge drawn from power source 204 so that the depth of discharge of power source 204 may be determined. For instance, Coulomb counter 206 may integrate the current delivered by power source 204 over time to determine an estimate of the amount of charge dissipated by power source 204. Coulomb counter 206 may, but need not, utilize the time provided by timer 218 to perform the integration. The charge dissipated by power source 204 may be provided to control circuit 210 for use in determine level of charge, depth of discharge, or some other metric indicative of a state of the power source 204.

As discussed above, control circuit 210 may control various aspects of the system, such as determining based on input from timer 218 when measurement logic 208 should take a sample of a monitored characteristic of power source. Control circuit may also control therapy module 211 to deliver therapy, may cause sensing module 213 to obtain sensed biological signals, may control generation of an ERI indication by ERI indicator 220, and so on. Examples of control circuit 210 include, but are not limited to, a processor such as a microprocessor, a digital signal processor (DSP), application specific integrated circuit (ASIC), field programmable logic array (FPGA), or other equivalent integrated or discrete logic circuitry. Control circuit may include one or more embedded storage devices similar to those discussed in regards to storage device 212.

Storage device 212 may comprise a computer-readable storage media, which may be a non-transitory storage medium. For purposes herein, “non-transitory” means the storage is not performed by a transitory, propagating signal. This term does not mean the storage medium is not removable or transportable. Examples of non-transitory storage device 212 include, but are not limited to, random access memory (RAM), read only memory (ROM), electrically erasable programmable read-only memory (EEPROM), CD-ROM or other optical disk storage, magnetic disk storage, or other magnetic storage devices, flash memory, or any other medium that can be used to carry or store desired program code in the form of instructions or data structures and that can be accessed by a computer or a processor. In some aspects, storage device 212 may include instructions that cause control circuit 210 to perform the functions ascribed to control circuit 210 in this disclosure.

Measurement logic 208 may be logic to measure values indicative of one or more characteristics of power source 204. For instance, measurement logic 208 may be a signal conditioning circuit or a signal processor. The characteristics of power source 204 that are monitored by measurement logic may include, among others, the voltage, pressure, temperature, impedance, and/or capacitance of power source 204. Measurement logic 208 provides the measured characteristic to control circuit 210. In some examples, measurement logic 208 provides its measurements to A/D converter 214. A/D converter 214 converts the measurement to a digital value and provides the digital value to control circuit 210 for use in generating an ERI indication. In other cases, analog measurements may be provided to control circuit 210 for use in generating an ERI indication.

In some examples, measurement logic 208 is substantially continuously monitoring, and acquiring values from, power source 204. For instance, a substantially continuous waveform may be obtained, provided to control circuit 210 for use according to techniques disclosed herein, and optionally stored within storage device 212. In other examples, measurement logic 208 is periodically obtaining values from power source 204 (e.g., at predetermined time intervals). Thus, measurement logic 208 may be supplying control circuit 210 with a continuous indication of a measured characteristic of power source 204 (e.g., a continuous waveform indicating output voltage). In this case, control circuit 210 may select which individual samples of the waveform to compare to the first and second thresholds. In another example, measurement logic 208 may instead be supplying control circuit 210 with discrete samples that indicate, at respective predetermined time periods, a value of the monitored characteristic. In any event, control circuit 210 may receive, or otherwise derive, discrete samples of values, wherein each sample is indicative of a state of the power source at a time substantially when the sample was acquired.

Control circuit 210 may compare each discrete sample to a first threshold to determine whether the sample has a first predetermined relationship to a first threshold (e.g., “less than, or “less than or equal to”, etc.) Once such a sample is located, control circuit 210 may begin to measure the time that elapses following receipt of this sample. This time period may be tracked by starting timer 218, for instance. Control circuit may also continue to monitor samples to determine whether another sample has a second predetermined relationship to a second threshold (“greater than or equal to”, greater than”, etc.). If control circuit 210 locates a sample having a second predetermined relationship to the second threshold before the monitored time period reaches the ERI threshold time, control circuit 210 may stop tracking the time, as by resetting timer 218. In this case, the power source 204 recovered from a high-current event in a sufficient period of time such that an ERI indication should not be generated. On the other hand, if a time period equal to the ERI threshold time expires prior to receipt of the second sample, an ERI indication may be generated.

As discussed above, various control parameters associated with ERI indication generation, such as the first and second thresholds, the first and second relationships to these thresholds, the ERI threshold time, and even the power source characteristic that is being tracked, may be programmably stored within storage device 212 and used by control circuit 210 to determine when to issue an ERI indication. In some examples, one or more of these parameters may be re-selected throughout the life of the power source 204.

ERI indicator 220 may comprise hardware, software, and/or firmware to generate one or more ERI indications to the patient upon control circuit 210 determining that an ERI indication should be provided. In one example, ERI indicator 220 may comprise an audible signal generator that generates a sound to alert patient 108 that ERI has been reached. In another example, ERI indicator 220 may cooperate with therapy module 211 to cause therapy module to deliver a discernible stimulation pattern to indicate to patient 108 that ERI has been reached. In some other cases, ERI indicator 220 may cause housing of IMD 110 to vibrate in a manner discernible by the patient. In yet another example, ERI indicator 220 may include logic to cause data to be sent via telemetry module 216 to an external device such as external programmer 116 to inform the user of the ERI indication. Such an indicator may be provided via a screen of a programmer, via some other type of indicator of the external device (e.g., an LED indicator), via a printer that provides a report informing the user of the ERI, via communication logic that generates a communication automatically to a user via a phone call, an email message, text message or some other message, or in any other manner. In some cases, programmer 116 or some other external device may automatically cause an alert to be sent to a clinician (e.g., via a telephone call, via an internet connection, or in some other manner) so that the clinician may then contact the patient to schedule a replacement procedure.

The various functional aspects shown in FIG. 2 may be implemented in hardware, software, firmware and/or any combination of any of these. The various blocks shown in FIG. 2 are intended to depict functional aspects of the disclosure, and not a manner in which logic is partitioned. Moreover, functional blocks may be shown in FIG. 2 interconnected to other functional blocks (e.g., via arrows). This is intended for example purposes, and should not be construed as limiting. For instance, although ERI indicator 220 is not shown to be connected via an arrow to telemetry module 216, in some examples, these two logical blocks may cooperate with one another to generate an ERI. Thus, the various partitioning of the blocks and interconnections there between are only provided for example purposes, and should not be considered limiting.

FIG. 3 is a graph illustrating use of aggregate sample values (e.g., values obtained via a rolling average) according to some methods of monitoring a power source. In this example, the output voltage of the power source is being monitored to determine when ERI should be indicated. Voltage is shown on the Y axis and time is depicted along the X axis.

FIG. 3 illustrates use of two waveforms: waveform 300 (shown as a solid waveform) and waveform 302 (shown dashed). Over some periods of time, these two waveforms coincide with one another.

The values used to construct waveform 300 are instantaneous signal values. In other words, each such signal value represents a state of the monitored signal at substantially a time the value was collected, and is not an aggregate value. Each such value is not obtained by averaging or somehow otherwise combining multiple measurements or values.

While waveform 300 is shown as a continuous waveform, it may be appreciated that this waveform may instead be depicted using a string of discrete points, each such point representing a respective one of the instantaneous sampled values. In some cases, a continuous waveform may be constructed from such discrete points by extrapolating between the discrete points (e.g., by “connecting the dots”). As the sampling rate increases such that the sampling period approaches zero, the plot of the samples will approach a continuous waveform.

In addition to waveform 300 shown using solid lines and curves, and which represents the instantaneous voltage values, waveform 302 is also depicted. Waveform 302 depicts use of aggregation. Each data point used to construct waveform 302 is obtained by processing multiple ones of the instantaneous samples represented by waveform 300, as by finding some type of an average or median value from these multiple samples. As an example, point 304 of waveform 302 may represent an aggregate, or composite, of the voltage values for all, or some, of the samples used to construction waveform during time period 306. Stated otherwise, example time period 306, which may be a rolling window, may be used to select samples (e.g., the N most recent samples) employed to calculate an aggregate value for point 304 of waveform 302. In this manner, the points that make up waveform 302 each represent some type of aggregated value of multiple instantaneous points that were collected during some prior period in time.

As discussed above, in some cases, waveforms 300 and 302 coincide. This will be the case, for instance, when the instantaneous voltage values are remaining relatively constant, as occurs during most of the useful life of the power source represented by FIG. 3. When the voltage levels are not changing, an aggregate value and the instantaneous value will be approximately the same. However, at times when the instantaneous voltage level is changing, the average voltage value will generally lag the instantaneous value. This can be seen, for instance, around the “knee” of the curve of FIG. 3 when the aggregate voltage levels of waveform 302 decline more slowly than the instantaneous values of waveform 300.

As may be appreciated, the use of aggregation acts as a low-pass filter, smoothing transient fluctuations in the signal. This type of low-pass filtering function can be useful in preventing the false triggering of an ERI indication. For instance, in the current example, it is desirable that an ERI indication be triggered at time T 310 when waveform 302 declines to the ERI threshold voltage level V_ERI 314. Providing an ERI at this time T 310 allows the user time (e.g., about 90 days in some examples) prior to reaching EOL to schedule a replacement surgery or take some other remedial action.

While it is desirable that ERI not be provided too close to EOL such that not enough time is allowed to take appropriate remedial action, it is also important that an ERI indication not be issued too early. For instance, a transient deviation in the power source voltage should not be allowed to trigger the issuance of an ERI well before the battery approaches EOL. This may prompt the explant of a device well before actually necessary, wasting healthcare resources and possibly subjecting the patient to additional surgeries over the course of their lifetime.

Transient deviations of the sort that could possible trigger false ERI may be caused by a high-current event that draws a relatively large amount of current from the power source. Such a high-current event could comprise a long-distance communication session that is opened between telemetry module 216 and external programmer 116, for instance. This type of operation draws substantial amounts of current, causing power source voltage to dip while the operation is taking place. As another example, in embodiments wherein therapy module 211 comprises a drug pump, delivery of substances via the pump may place a high current demand on power source 204, causing voltage of the power source to dip below the ERI threshold for the period of pump operation. Yet another example may relate to the momentary delivery of high currents via therapy module 211 for some types of high-current electrical stimulation therapy, which may also cause a drop of power source voltage. These, and other types of high-current operations, may cause some monitored characteristic of power source to change momentarily such that measured values for the characteristic (e.g., sample values) attain some predetermined relationship to an ERI threshold, thereby falsely triggering ERI.

The foregoing is exemplified in FIG. 3. A temporary drop 322 in the voltage of power source is shown in waveform 300 of the type that could be the result of a high-current event. An expanded view 324 of this voltage drop 322 shows that the instantaneous voltage falls below an ERI threshold voltage V_ERI used to trigger an ERI. However, the aggregate signal values represented by waveform 302 (dashed) “lag” the values represented by waveform 300. Waveform 302 dips more slowly than the sharper drop exhibited by waveform 300, and therefore does not drop below voltage threshold V_ERI before the voltage level of the power source recovers and once again rising above V_ERI after the high-current event is over. In this manner, the use of aggregation may prevent the false triggering of ERI in some cases.

In the example of FIG. 3, the amount of time during which the instantaneous voltage of power source 204 is below V_ERI is shown as being about 1 day. This means that following the end of the high-current event that prompted the deviation 322, one day passed before the power source output voltage again reached levels exceeding V_ERI. This type of recovery period may be somewhat typical of some high-rate batteries. Some other types of power sources may require significantly longer to recover following a high-current event. For instance, medium-rate batteries, including the types described herein, may require three, four, or even more days for voltage to exceed V_ERI following cessation of a high current event. One way to address this extended recovery time is to utilize a longer averaging period in obtaining the average values used to trigger ERI indications (e.g., increase the length of rolling window 306). This will allow more samples to be included in each averaged value, thereby slowing the rate at which waveform 302 responds to changes in the output voltage signal (or some other monitored characteristic of power source 204.) However, if the period 306 is increased too much, the lag between waveform 302 and waveform 300 will grow to be too large around the “knee” in the voltage curve that occurs as EOL approaches. As a result, an ERI indication may be provided too late to allow adequate time to take action prior to EOL. Thus, simply increasing the averaging period is not sufficient to both prevent the false triggering of ERI and to also provide timely notification of ERI as EOL approaches. This is illustrated in FIG. 4.

FIG. 4 is a graph illustrating how use of aggregation can result in the false issuance of ERI. This graph is similar to that shown in FIG. 3, with the example power source characteristic (again, output voltage) shown on the Y axis and time illustrated on the X axis. Instantaneous values (e.g., samples) of the power source voltage are used to construct waveform 400, whereas aggregated values are used to construction waveform 402 in a manner similar to that shown in FIG. 3. Again, it is desirable that ERI not be triggered until time T 410 when waveform 402 crosses the ERI voltage threshold V_ERI 414.

As was the case in the example of FIG. 3, a high-current event causes a transient deviation 422 in the monitored power source voltage. This is shown in an expanded view 424. In this case, a medium-rate power source is being employed. As such, when the power source voltage dips as a result of the high-current event, as shown by instantaneous values of waveform 400 in expanded view 424, it takes multiple days (in this case, 3 days) to recover. Thus, the voltage may remain below the voltage threshold V_ERI 414 for this extended period of time. This results in the aggregate values also dipping below V_ERI, as shown by waveform 402, which is shown crossing this threshold in the expanded view 424 at point 425. This falsely triggers ERI at time T1 430, well before it is desirable to do so. This will waste healthcare resources and may subject the patient to unnecessary surgical procedures over the course of a lifetime. As discussed above, while increasing the averaging period may prevent the false triggering of ERI too early, this will delay the time when ERI crosses V_ERI after the knee of the voltage curve is reached around T″432, possibly resulting in providing ERI too close to EOL so that the patient does not have time to plan for EOL.

In accordance with the current disclosure, mechanisms are provided for utilizing the instantaneous values (e.g., the values used to construct waveform 300) to determine when ERI is to be issued. This is exemplified in FIG. 5.

FIG. 5 is a timing diagram illustrating use of instantaneous values to trigger ERI. As was the case with FIGS. 3 and 4, the example of FIG. 5 discusses use of power source voltage measurements to construct waveform 500. This waveform may be based on instantaneous sample values obtained from measurement of the monitored characteristic. In some examples, extrapolation between such samples may be used to gain the continuous waveform 500. “Instantaneous” sample values means each value represents a single measurement indicative of a state of the power source at a time associated with that sample. For instance, the time may be the time substantially when the signal value was obtained or sampled. A sample may be a “raw” signal sample obtained from measurement logic 208 and provided to control circuit 210, or may be processed in some manner (e.g., digitized by A/D converter 214, filtered in some manner, and so on.) Each such sample value used to construct waveform 500 is a non-aggregate value in that it is not based on more than one measurement, or sample, of the monitored power source characteristic as would be the case with aggregate values (e.g., averaged or median values) as discussed in relation to waveforms 302 and 402 of FIGS. 3 and 4, respectively.

FIG. 5 illustrates voltage measurements taken during a high-current event of the type illustrated in expanded views 324 and 424 of FIGS. 3 and 4, respectively. During the high-current event, the voltage of the power source is pulled down for some period of time, as shown in waveform 500. Eventually, the voltage will recover to a level that approximates the pre-event levels, as occurs following cessation of the high-current event To determine whether ERI should be issued, the individual samples of the monitored characteristic (e.g., the samples of the output voltage of the power source) are compared to a first threshold (in this case, a voltage threshold). When a sample is detected that has a first predetermined relationship to this first threshold, the start of a time period is indicated. The predetermined relationship may be any type of relationship (e.g., greater than, less than, etc.).

In the instant example, samples used to construct waveform 500 are compared to first threshold 502 to determine whether a sample is received that have a value that is less than this first threshold. In this example, a first sample having this first relationship is obtained at substantially time T1 504. Receipt of this sample will be used to mark the start of a monitored time period. For instance, in one example, receipt of this sample may be used by control circuit 210 to start timer 218, which will expire when the ERI threshold time elapses. In another example, control circuit 210 may receive a time stamp from timer 218 that indicates the start of the time period. Other ways of indicating the start of the time period may be contemplated by those skilled in the art.

Next, samples may be monitored to determine when a sample is received that has a second predetermined relationship to a second threshold 506. FIG. 5 illustrates an example wherein the second threshold is substantially the same as the first threshold, although this need not be the case. As was the case with the first predetermined relationship used to compare samples to the first threshold, the second predetermined relationship may be any desired relationship (e.g., greater than or equal to, less than, etc.), and the selected relationship will generally be based on the type of power source characteristic being monitored. In this example, the relationship is “greater than or equal to”.

When an instantaneous sample is received that has a value having this second predetermined relationship to the second threshold, as occurs substantially at time T2 508 in the example of FIG. 5, tracking of the time period may be stopped, as by resetting timer 218 (assuming the timer hasn't already expired). Thus, if the second sample received at time T2 508 is received prior to expiration of the ERI threshold time, the timer will not expire and no ERI indication will be issued. On the other hand, if the second sample is not received before expiration of the ERI threshold time (e.g., as indicated by expiration of timer 218), an ERI indication will be initiated by control circuit 210.

In the example of FIG. 5, and time T2−T1 between the first and second samples is indicated by arrow 510. Assuming in FIG. 5 that the first ERI threshold time 512 is used to determine whether an ERI indication will be generated, an ERI will not be issued because the time period between the first and second samples, T2−T1, is not greater than first ERI threshold time 512 and the timer 218 will not expire prior to time T2. On the other hand, if the second ERI threshold time 514 is used instead to determine whether an ERI indication will be generated, an ERI will be issued because T2−T1 is greater than second ERI threshold time 514, and timer 218 will expire before the second sample is received.

In one example, one or more of the first and second thresholds, the first and second relationships used to compare samples to the first and second thresholds, respectively, and the ERI threshold time may be programmable. For instance, they may be programmably selected by a manufacturer based on a known application of IMD 110 or based on the particular type of battery. In some cases, one or more of these values may be programmably selected by a clinician or even a patient. As discussed further below, these values may even be adaptable such that they are re-selected one or more times during the lifetime of IMD 110. For example, the values may be selected based on the charge level or depth of discharge of power source, as may be determined based on a measure of Coulomb counter 206, which may be provided within IMD 110 in some embodiments to track the amount of charge depleted from power source 204 over its lifetime.

In some embodiments, it may be desirable to record the time between the first and second samples. This type of information may be used to determine whether the ERI algorithm needs to be adapted based on usage of the system, as will be discussed further below. In this case, control circuit 210 may receive first and second time stamps from timer 218 for association with the first and second samples, respectively. This allows a time between receipt of the first and second samples to be derived by subtracting the first timestamp from the second timestamp (e.g., as by T2−T1.) This time information may be saved in storage device 212 for analysis purposes, if desired.

FIG. 6 is another timing diagram illustrating techniques according to the current disclosure. In a manner similar to that shown in FIG. 5, waveform 600 represents a plot constructed from sampling values of a power source characteristic and plotting these individual values (rather than by plotting values that represent some sort of aggregate of multiple values, such as median or averaged values.)

In this example, two high-current events are shown in sequence. A first high-current event results in a signal value being received at time T1 602 that has a predetermined relationship to (e.g., is less than) the first threshold 604. This marks the start of a time period as discussed above in regards to FIG. 5. A second signal value is received at time T2 606 that has a second predetermined relationship (in this case, greater than or equal to) the second threshold 608. In this simple example, the first 604 and second 608 thresholds are the same, but this need not be the case if, for instance, hysteresis is added to the system. The time between the first and second samples (e.g., T2−T1, as indicated be arrow 612), is not greater than the ERI threshold time 610. Therefore, the ERI threshold time will not expire before control circuit 210 receives the second sample associated with time T2, and an ERI is therefore not generated.

Sometime later, a second high-current event again causes the monitored signal to drop below the first threshold 604 at time T1′ 616. Monitoring of the signal continues looking for a signal value that is greater than, or equal to, the second threshold at time T2′ 618. In this second case, this signal value would not be acquired until time T2′. However, before this signal is obtained, the ERI threshold time 610 expires at time T3. This may be signaled by expiration of timer 218 that is timing the ERI threshold time. Therefore, an ERI indication is generated. This indication may be generated anytime after the ERI threshold time 610 is exceeded without the monitored signal having attained the predetermined relationship to the second threshold (e.g., substantially at time T3 622).

The example of FIG. 6 illustrates how the window of time T2−T1 is effectively “re-set” after a high-current event ends without time T2−T1 exceeding ERI threshold time 610. That is, once the first high-current event ends based on the sample being received at time T2 606, there is no “memory” of this first high-current event that affects the way the second high-current event is handled. In an example that uses timer 218 to time the ERI threshold time, the timer 218 may be reset upon receipt of the second sample at time T2. When another high-current event occurs, the timer is re-started without regard to whether the previously-monitored time period T2−T1 was only a little shorter than the ERI threshold time or substantially shorter than the ERI threshold time. The monitored time period associated with the second high-current event is evaluated “on its own” without consideration of the length of the first high-current event. This reduces some of the “carryover” effect associated with aggregation, which allows history of past performance to affect how ERI monitoring is performed.

As an example of the foregoing, waveform 624 (shown dashed) may represent aggregate values of a monitored characteristic, such as a rolling average of the instantaneous signal values from waveform 600. This waveform 624 lags waveform 600 because of the “carryover” effect discussed above. After this waveform 624 crosses the first threshold 604 sometime after time T1 602, it remains below the second threshold at time T2 606 even though waveform 600 that represents the instantaneous values does rise above the second threshold. Thus, if aggregation were relied upon to trigger ERI, an ERI indication would have been undesirably generated at time 626 upon expiration of the ERI threshold time.

As may be appreciated, the use of aggregation effectively creates a memory of previous high-current events. If multiple high-current events are occurring one after the other, this memory of past occurrences may cause aggregate values to be affected in a way that may trigger false ERI indications. While instantaneous values may likewise be affected by past events (e.g., because the battery cannot recover immediately from such events and instantaneous signal values of monitored battery characteristics will generally reflect this), the impact is not as large as when aggregation is employed. For instance, the current disclosure may sufficiently handle a situation wherein a battery does not fully recover for 3 or more days during which time over four thousand samples may be acquired if sampling is occurring at a rate of one sample per minute.

The foregoing examples provide simple scenarios involving the first and second relationships that are used with the first and second thresholds, respectively. In some other examples, more complex predetermined relationships may be used for comparing samples of the monitored signals to the first or second threshold. For instance, a relationship may be defined to have a time component. Assume, for example, the second relationship that is used with the second threshold is defined to be “greater than or equal to for at least some predetermined period of time TT. In other words, for the relationship to be satisfied, a sample of the monitored signal must be obtained that has a value “greater than or equal to” the second threshold and all subsequent samples collected during time period TT must likewise have a value that equals, or exceeds, this second threshold.

As an example of the foregoing, if arrow 616 represents time TT, time T2 606 would not mark the end of the first time period associated with the first high-current event. Instead, monitoring would continue for an additional time period TT 616 to see if the values of waveform remain above the second threshold 608. If so, the expiration of time TT 616 would mark the end of the first high-current event. As can be seen by FIG. 6, the values of waveform 600 dropped below the second threshold 608 before expiration of time TT 616. Therefore, the second relationship associated with the second threshold is not met until time T4 608 when the signal level remains greater than or equal to the second threshold for at least the time TT. Therefore, in this case, the first high-current event would trigger an ERI indication at the expiration of ERI threshold time 610 sometime shortly after T2.

As may be appreciated, the relationships selected to mark the beginning and end of the monitored time period that is compared to the ERI threshold time may be defined to be as simple or complex as desired. In some cases, these relationships may be defined using Boolean logic, time periods, and so on. In examples, these relationships may be programmable selected. In some cases, the relationships are predetermined by a manufacturer and are not changeable by an end-user (e.g., a clinician or patient.) In other cases, an end user is allowed to select the relationships.

FIG. 7 is another timing diagram illustrating techniques according to the current disclosure. Waveform 700 represent a plot constructed from sampling values of a power source characteristic and plotting these individual instantaneous values in waveform 700. As with any of the examples discussed herein, the instantaneous values used to plot waveform 700 may be obtained substantially continuously in real time so that a continuous waveform is being plotted. The time represented by each sample may approach zero in such cases.

In the example of FIG. 7, first and second thresholds 702 and 704 respectively are not the same. In particular, the second threshold has a greater value than the first threshold, although in other examples, the first threshold may have a value greater than the second threshold. This may add hysteresis to the system.

According to this example, some event (e.g., a high-current event, or some other event that cases a momentary drop in voltage) results in a signal value being received at time T1 706 that has a predetermined relationship to (e.g., is less than) the first threshold 702. This marks the start of a monitored time period as discussed above in regards to FIGS. 5 and 6. Monitoring of signal values continues, and another signal value is received at time T2 708 that has a second predetermined relationship (in this case, greater than or equal) to the second threshold 704. Again, in this example, the second threshold is greater than the first threshold. The monitored time period T2−T1 does not exceed the predetermined ERI threshold time 710 and no ERI indication will be generated. Tracking of the time following receipt of the first sample (at time T1) will cease at time T2 (e.g., by resetting timer 218) and any subsequent high-current event will not be associated with a “memory” of the high-current event shown in FIG. 7 other than to the extent the instantaneous values remain affected by that previous high-current event.

The foregoing examples illustrate how instantaneous, non-aggregate values of a signal that represent a state of a power source 204 may be obtained and used directly to determine when to issue an ERI. Using this approach, more accurate ERI indications may be generated for some power source chemistries, such as those associated with medium-rate batteries. While medium-rate batteries are used as an example, other types of power sources may likewise usefully benefit from the techniques disclosed herein.

FIG. 8 is a flow diagram illustrating one embodiment of a method according to the current disclosure. A signal that is indicative of a characteristic of a power source may be sampled (800). As discussed above, sampling of the signal refers to acquiring sample values, each having a value that indicates a state of the power source at substantially a same time as that sample was acquired. This may involve use of some type of sampling circuit. Sampling may be performed in software, hardware, or some combination thereof. In some cases, sampling may be performed substantially continuously and in real-time so that the sampled values define a substantially continuous waveform. Predetermined ones of these values (e.g., every Nth recorded signal) may be selected for use in performing processing according to techniques described herein. In other cases, a sampled value may be obtained less frequently (e.g., every minute, every 15 minutes, every hour, every day, etc.) Any such sampling time may be selected. Generally, the sampling time will be selected based on a chemistry of the power source, based on a desired accuracy for providing the ERI indication, based on an amount of power and processing time dedicated to sampling activities, and so on. In one embodiment, signal samples are collected once every minute for a medium-rate chemistry battery. The sampling rate may be programmable in some cases.

As described above, it may be desirable to collect signal samples only during times of light loading, since collecting signal samples during times of heavy loading may not provide useful information and may unnecessarily waste processing and other system resources. Moreover, in some cases, it may be desirable to obtain a sample after the power source has had a maximum time to recover from any previous high-current event since this will provide the most information about the state of the power source. Thus, some examples may sample power source 204 shortly after control circuit 210 (e.g., processor) exits an idle state and before any high-current event such as a long-range telemetry session, charging for a pump operation, or use of a high-current sensor is initiated.

The monitored characteristic may be selected based on a type of power source. In some cases, it may be desirable to monitor output voltage of the power source. In other case, it may be more accurate to monitor power source impedance of capacitance, which may increase over time, and which may also momentarily increase during a high-current event. In some cases, the characteristic being monitored may be programmably selected.

As values are being obtained for the monitored signal, it may be determined (810) whether a first relationship (“Relationship1”) exists between each individual discrete value S1 of the signal (e.g., an obtained sample value S1) and a first threshold (“Thresh1”). As described above, both the first relationship and the first threshold may be any type of threshold and relationship that is appropriate for the particular power source and characteristic being monitored. For instance, in examples that monitor the characteristic of output voltage, it may be desirable to select as the first relationship “less than” or “less than or equal to”. The threshold for a medium-rate battery such as a Li—CFx battery may be selected as between 2 and 3 volts and in some examples is 2.75 volts. In some cases, the threshold may be defined as a percentage of the monitored characteristic at a particular charge level or depth of discharge (e.g., 10% below the nominal output voltage level when the power source is lightly loaded at a 90% charge level, etc.) Other mechanisms for selecting the thresholds may be used. One or more of these values may be programmable, either by manufacturer, clinician, or another end user.

If the first relationship is not found to be met by a value obtained for the signal being monitored, sampling (800) of the signal may continue while looking for a sample that satisfies the first relationship. On the other hand, if this first relationship, Relationship1, is determined to have been met by a sample S1, a timer may be started (815). For instance, the timer may be initialized to the ERI threshold time and then started to decrement to zero. Alternatively, measuring of the time period may be performed in another way.

In some cases, the ERI threshold time is a predetermined length of time that may range from one to five days. In one specific case, the ERI threshold time is three days. This value may be selected so that it does not significantly impact a time between generation of a legitimate ERI indication and generation of an EOL indication. For instance, if the time period is too long, it may reduce the time between an ERI indication and the EOL indication to something that is substantially less than 90 days, which may be undesirable.

Following receipt of a sample that satisfies the first relationship, more signal values may be obtained (820). For each of these obtained values (e.g., each sample S2), it may be determined (830) whether a second relationship (“Relationship2”) exists between the sampled value and the second threshold (“Thresh2”). This second relationship may be “greater than” or “greater than or equal to”. In one example, the threshold is between 2 and 3 voltage, and in a particular example is 2.75 volts, although other values may be selected.

If the second relationship does exist between the sampled value and the second threshold, the timer may be cleared (835) or monitoring of the time period may be stopped in another way. Processing may return to step 800 where monitoring for a sample that satisfies the first relationship may begin again. If, however, the obtained sample value does not have the second relationship to the second threshold, processing proceeds to step 840 where it may be determined whether the monitored time period has a length equal to, or exceeding, (or in some embodiments, just “exceeding”) the ERI threshold time. This may be accomplished, for example, by determining whether a timer expired. If not, additional samples may be acquired in step 820 and the process of comparing these samples to the second threshold may continue.

If, in step 840, the ERI threshold time has expired, an ERI indication may be issued (850). This may be accomplished by providing any type of mechanism that can alert a machine or person of the ERI. This may be an audible alert, visual alert, tactile alert (e.g., a vibration or stimulation pattern), some other electronic alert that sends an email, text, telephonic, and/or any other sort of message or other notification sent to a user or an electronic system.

As discussed above, in some cases, it may be desirable to adapt various parameters used in the systems and methods described herein. For instance, it may be desirable to change the values of one or more of the first and second thresholds, the first and second predetermined relationships, the ERI threshold time, and even the monitored power source characteristic that is used to indicate an ERI should be issued. One or more of these values may be adapted based on conditions existing within the system. As a battery grows more depleted, for example, the recovery times may increase over time. Depletion of the battery may be quantified by obtaining an indication from Coulomb counter 206 of the charge already depleted from power source 204. Based on this indication from Coulomb Counter, control circuit 210 may select an ERI threshold time (or one or more of the other parameters) that coincides with the Coulomb counter reading. For instance, storage device 212 may store a lookup table that maps Coulomb counter readings to one or more of the parameters. This may allow the algorithm that is used to issue an ERI to adapt over time based on the state of power source 204.

In another example, other parameters may be used to adapt one or more parameters based on a state of the system. For example, a temperature of the power source 204 may be obtained (e.g., via a temperature measuring circuit or other logic of measurement logic 208.) This temperature of the power source may be used to adapt one or more of the parameters used by the disclosed methods. Again, in one example, lookup tables or other data structures stored with storage device 212 may be used to map a temperature to the one or more parameters such as one or more of the first and second thresholds used in FIG. 8.

Still other example conditions that may be used to adapt various parameters may include impedance, capacitance, or some other measure indicating an overall state of power source 204.

In one case, the way the system is being employed may determine one or more values to be used to issue the ERI indication. For instance, for some patients, it may be desirable or necessary to more frequently initiate high-current events. As a specific example, because of a patient's condition, it may be necessary to use sensing module 213 to take frequent periodic readings (e.g., monitor blood sugar, blood pressure, etc.) It may further be necessary to regularly or semi-regularly transmit the sensed data to an external system for monitoring and analysis. In this type of application, there may be repeated high-current events that occur within a short period of time of one another. Because power source 204 may not have time to fully recover between such high-current events, it may be desirable to select a longer ERI threshold time for use with this application.

In some cases, the way the system is being used may change over the life of the device. For instance, following implantation, it may be desirable to initiate a relatively high number of high-current events within short periods of time, as may be the case if sensing module 213 is being used to track the condition of the patient more closely. Sometime later, after a patient's condition may be known to be stable, monitoring may be considered less critical, and fewer high-current events may therefore be initiated. In this case, it may be desirable to initially select a longer ERI threshold time period so that a sequence of high-current events occurring early-on in the life of the device will not falsely trigger ERI. Later in the life of the device, the ERI threshold time may be programmably shortened to account for the fact that the way the system is being used is changing.

In one example, time stamps may be associated with acquired samples so that times between first and second samples (e.g., T2−T1, as shown in FIG. 5) may be determined. The system may perform analysis to determine if, even when the power source is relatively new, T2−T1 is approaching the selected ERI threshold time. If that is the case, it may be desirable to lengthen the ERI threshold time, for example.

The time T2−T1 may further be used, in some cases, to predict when an ERI issuance will finally be triggered. For instance, throughout the life of a device that is used in a relatively consistent manner, and in which samples are taken in a consistent way (e.g., always sampled substantially after a processor wakes up from idle state and prior to high-current events) the time T2−T1 may remain relatively consistent as well. As the battery approaches the knee of a voltage curve (e.g., FIG. 3), however, time T2−T1 may begin to lengthen even before the ERI indication is issued. This may provide a level of “pre-warning” that battery end-of-life is approaching. In some cases, this information may be provided to a user, as by transferring information to an external device via a telemetry session.

FIG. 9 is a flow diagram illustrating an example method for adapting parameters used to determine an ERI indication according to the current disclosure. Such parameters may include the first and second thresholds, the first and second relationships to be used with these thresholds, the ERI threshold time, and so on.

Information may be obtained (900) that is indicative of an aspect of the system that may relate to power usage. In one example, this value may be a charge level or level of depletion of power source 204, as may be determined based on information obtained from Coulomb counter 206. In another case, this may be some indication of use of the system, such as times between high-current events, or a time T2−T1 between receipt of samples S2 and S1 (e.g., FIG. 8). Based on this obtained information, values of one or more of the parameters used to trigger ERI issuance (e.g., FIG. 8) may be determined (920). For instance, tables may be loaded into storage device 212 that map various system parameter values, parameter ranges and/or conditions to various parameters that may be used to determine ERI issuance. The system parameter ranges and conditions may include ranges of depth of discharge of power source 204, ranges for T2−T1, conditions associated with use (e.g., high frequency high-current use, etc.), and so on. Control circuit 210 may use the system parameters and conditions to access an appropriate table entry to obtain the ERI parameters to use to determine when to issue the ERI indication. In some cases, only some of the parameters used to determine an ERI indication may be considered adaptable, while other are considered “hard coded” and are not programmably re-selected.

Thereafter, non-aggregated signal values (e.g., the instantaneous sample values) may be used to monitor for ERI (930). As discussed above, an aggregate signal value is a value obtain by processing multiple values (e.g., using averaging, by determining a median value, etc.), whereas a non-aggregated signal value refers to a single instantaneous value of the type that may be based on a single measurement. According to current techniques as discussed herein, the values used to determine ERI are not aggregate values, but rather values that reflect a single signal sample and have a value indicative of the state of the power source at the time the single signal sample was acquired.

A check (930) may be performed to determine whether the ERI method should be adapted. This may involve checking a system condition to determine if it has changed such that parameters for the ERI mechanism should be updated. Alternatively or additionally, this may involve determining that a period of time has expired such that adapting the parameter value(s) for the ERI mechanism may be required. Some other condition or input may be used by check 930 to determine whether adaptation is needed or desired, such as input provided by a user that may indicate adaptation should be performed, and so on. If adaptation is not required, processing continues with step 920. There, monitoring signals to determine whether an ERI indication should be issued according to systems and methods described herein continues. Otherwise, processing may proceed to step 900, where a value indicative of the state of the system may be determined for use in adapting one or more parameters of the ERI method.

FIG. 10 is an example method of obtaining samples that may be used to determine when an ERI indication should be indicated. A control circuit 210 (e.g., a microprocessor) may enter an idle state for a predetermined amount of time (1000). The predetermined amount of time may be minutes, an hour, several hours, and so on. Use of this type of idle period may help conserve power since the control circuit 210 may enter a low-power state during this idle period.

Sometime after exiting this idle state, and in some cases relatively soon after existing this idle state, control circuit 210 may obtain a sample value for a power source characteristic according to mechanisms described herein (1010). This sample value may be obtained at a time the power source 204 is lightly loaded. For purposes herein, the power source is lightly loaded if no high-current events are occurring within the system such that only a background current is being drawn from the power source. Such background current may be less than 100 μA in some examples, and may be between 10 μA and 50 μA. Since the control circuit 210 was in the idle state for a predetermined amount of time during which no high-current events were occurring (1000). Therefore, it may be concluded that at least this predetermined amount of time has passed between the occurrence of a most-recent high-current event and the acquisition of the sample. The power source 204 has had at least this predetermined amount of recovery time since the last high-current event, which may allow the sample to be more informative of the actual state of the power source.

The acquired sample may be processed (1020) according to techniques described herein for use in determining whether to issue an ERI indication. This may result in issuance of an ERI indication as described herein. The sample acquisition and processing may occur prior to initiation of any high-current event. Moreover, this may occur when power source 204 has had a maximum time to recover from any previous high-current event. This may allow for improved ERI processing since samples will be more informative of the state of the power source 204 than if such samples were acquired either during, or even right after, high-current events.

Sometime after sample acquisition in step 1010, one or more high-current events may be initiated (1030). If device EOL has not been reached (1040), processing may continue in this manner such that the control circuit 210 may return to step 1010 to once again enter an idle state for a predetermined period of time. When device EOL has been reached (1040), the EOL indication may be generated and special processing may be performed (1050). For instance, at this time, it may be desirable to limit frequency of high-current events and enter a “standby” mode until device replacement may be scheduled.

In the example of FIG. 10, a sample is shown to be acquired after exiting an idle and prior to initiating one or more high-current events. This is merely an example. For instance, in step 1010, multiple samples may be acquired over time (e.g., at predetermined time increments) prior to initiating any high-current events in step 1030. Additionally, one or more samples may be obtained following step 1030 and prior to returning to step 1000. Again, these one or more samples may be obtained over time at predetermined time increments. As previously discussed, samples may likewise be collected during the one or more high-current events, although the information available from such samples may be limited. Thus, FIG. 10 provides only one example, and is not limiting.

The techniques described in this disclosure, including those attributed to control circuit 210, Coulomb counter 206, measurement logic 208, A/D converter 214, timer 218, or various constituent components, may be implemented, at least in part, in hardware, software, firmware or any combination thereof. For example, various aspects of the techniques may be implemented within one or more processors, e.g., control circuit 210, including one or more microprocessors, digital signal processors (DSPs), application specific integrated circuits (ASICs), field programmable gate arrays (FPGAs), or any other equivalent integrated or discrete logic circuitry, as well as any combinations of such components, embodied in programmers, such as physician or patient programmers, stimulators, image processing devices or other devices. The term “processor” or “processing circuitry” may generally refer to any of the foregoing logic circuitry, alone or in combination with other logic circuitry, or any other equivalent circuitry.

Such hardware, software, and/or firmware may be implemented within the same device or within separate devices to support the various operations and functions described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware or software components. Rather, functionality associated with one or more modules or units may be performed by separate hardware or software components, or integrated within common or separate hardware or software components.

While aspects of this disclosure are described in reference to a medium rate battery, it will be understood that other battery technologies (e.g., high-rate technologies) and other types of power sources may usefully employ the techniques described herein.

When implemented in software, the functionality ascribed to the systems, devices and techniques described in this disclosure may be embodied as instructions on a computer-readable medium such as random access memory (RAM), read-only memory (ROM), non-volatile random access memory (NVRAM), electrically erasable programmable read-only memory (EEPROM), FLASH memory, magnetic data storage media, optical data storage media, or the like. The instructions may be executed to support one or more aspects of the functionality described in this disclosure.

In some cases, control logic that performs functions such as those described herein may be located in the IMD, an external device such as the programmer, or both. For instance, control logic within IMD may control acquisition of signal samples (or some other logic within IMD may control this function). These signals may then be transferred to an external device where control logic within a programmer may determine whether the samples indicate an ERI indication should be issued. In other examples, some of the processing steps involving the samples of the monitored power source characteristic may be performed within the IMD, intermediate results may be transferred by the IMD to an external device such as a programmer, and the external device may complete processing to determine whether an ERI indication should be issued. Thus, many examples exist for processing of the samples using control logic within IMD and/or control logic within programmer.

In general, the techniques described in this disclosure can be applied to devices that are powered by one or more power sources such as batteries or capacitors. The techniques may be applied to medical devices such implantable medical devices configured to deliver neurostimulation or other electrical stimulation therapy via implanted electrode arrays, carried by leads or otherwise, located proximate to the spinal cord, pelvic nerves, peripheral nerves, the stomach or other gastrointestinal organs, or within the brain of a patient. The techniques described in this disclosure can be applied to medical devices that may not include electrodes to provide electrical stimulation. For examples, the techniques described in this disclosure can be applied to medical devices that provide medication in accordance with a delivery schedule. The techniques described in this disclosure may also be applied to medical devices that are external to the patient, as well as medical devices that used to program other medical devices. The techniques described in this disclosure may also be applied to non-medical devices such as laptop computers, gaming counsels, mobile phones, personal digital assistants (PDAs), and other such devices.

Many aspects of the disclosure have been described. Various modifications may be made without departing from the scope of the claims. These and other aspects are within the scope of the following claims.

1. A method for monitoring a power source of an implantable medical device, comprising:
sampling a signal indicative of a characteristic of the power source;
determining, by a control circuit, when a first sample of the signal having a first predetermined relationship to a first threshold is received; and
issuing, by the control circuit, an elective replacement indication if at least a predetermined amount of time elapses after receipt of the first sample and before receipt of a second sample of the signal having a second predetermined relationship to a second threshold.

2. The method of claim 1, wherein the characteristic is an output voltage level of the power source.

3. The method of claim 2, wherein sampling comprises sampling a signal indicative of a characteristic of the power source when the power source is lightly loaded.

4. The method of claim 2, wherein sampling the signal comprises obtaining a value indicative of the signal at substantially a time the value is obtained.

5. The method of claim 1, wherein the first predetermined relationship is “less than”, or “less than or equal to”, and wherein the second predetermined relationship is “greater than or equal to” or “greater than”, respectively.

6. The method of claim 1, wherein at least one of the first and second predetermined relationships is defined based, in part, on a period of time.

7. The method of claim 1, wherein the first and second thresholds are substantially equal.

8. The method of claim 1, further comprising allowing a user to select at least one of the first threshold, the second threshold, the first relationship, the second relationship and the predetermined amount of time.

9. The method of claim 1, wherein at least one of the first threshold, second threshold, and the predetermined amount of time may be automatically adjusted.

10. The method of claim 1, wherein sampling the signal comprises sampling the signal at least some predetermined amount of time since an occurrence of a most-recent high-current event.

11. The method of claim 1, further comprising:
monitoring a time period that follows receipt of the first sample; and
discontinuing monitoring of the time period if the second sample is received prior to expiration of the predetermined amount of time.

12. The method of claim 11, wherein monitoring the time period comprises starting a timer and wherein discontinuing monitoring of the time period comprises clearing the timer.

13. A system, comprising:
a power source configured to be implantable within a patient;
measurement logic configured to obtain samples of a signal indicative of a characteristic of the power source; and
a control circuit configured to determine when a first sample of the signal having a first predetermined relationship to a first threshold is received, and to initiate issuance of an elective replacement indication if a predetermined amount of time elapses following receipt of the first sample and before receipt of a second sample of the signal having a second predetermined relationship to a second threshold.

14. The system of claim 13, wherein the measurement logic is configured to obtain samples of an output voltage level of the power source.

15. The system of claim 14, wherein the measurement logic is configured to obtain samples during a time when the power source is lightly loaded.

16. The system of claim 14, wherein the measurement logic is configured to obtain samples that are each indicative of a value of the signal at the time the sample is obtained.

17. The system of claim 14, wherein the first predetermined relationship is “less than”, or “less than or equal to”, and wherein the second predetermined relationship is “greater than or equal to” or “greater than”, respectively.

18. The system of claim 13, wherein the first and second thresholds are substantially equal.

19. The system of claim 13, further comprising a user interface to allow a user to programmably select at least one of the first threshold, the second threshold and the predetermined amount of time.

20. The system of claim 13, wherein the control circuit is configured to automatically adjust at least one of the first threshold, the second threshold, and the predetermined amount of time.

21. The system of claim 13, wherein an implantable medical device comprises the control circuit.

22. The system of claim 13, wherein a device external to a patient comprises the control circuit.

23. The system of claim 13, further comprising a timer, and wherein the control circuit is configured to start the timer upon receipt of the first sample and to clear the timer upon receipt of the second sample if the second sample is received prior to expiration of the predetermined period of time.

24. The system of claim 23, wherein the timer is configured to measure the predetermined amount of time, and wherein the control circuit is configured to initiate issuance of the elective replacement indication if the timer expires before receipt of the second sample of the signal having the second predetermined relationship to the second threshold.

25. An implantable medical device, comprising:
a power source;
measurement logic configured to obtain samples of a signal indicative of a characteristic of the power source; and
a control circuit configured to determine when a first sample of the signal having a first predetermined relationship to a first threshold is received, and to initiate issuance of an elective replacement indication if at least a predetermined period of time elapses following receipt of the first sample and before receipt of a second sample of the signal having a second predetermined relationship to a second threshold.

26. The implantable medical device of claim 25, wherein the power source is a medium-rate battery.

27. The implantable medical device of claim 25, further comprising a timer configured to time the predetermined period of time.

28. The implantable medical device of claim 27, wherein the timer is configured to determine when to obtain the samples.

29. The implantable medical device of claim 25, wherein the control circuit is configured to cause the measurement logic to obtain the samples only during time periods wherein the power source is lightly loaded.

30. A non-transitory storage medium storing instructions to cause a control circuit to:
receive samples of a signal indicative of a characteristic of the power source;
determine when a first sample of the received samples has a first predetermined relationship to a first threshold; and
issue an elective replacement indication if a predetermined period of time elapses after receipt of the first sample and before receipt of a second sample of the signal having a second predetermined relationship to a second threshold.
